(19) United States
(12) Patent Application Publication
(10) Pub. No.: US 2001/0033236 A1
(43) Pub. Date: Oct. 25, 2001

(54) Method for encoding and decoding data streams representing sounds in digital form inside a synthesizer

(75) Inventors: Enrico Iori, Modena (IT); Thomas Serafini, Modena (IT)

Correspondence Address: MODIANO & ASSOCIATI, Via Meravigli, 16, MILANO, 20123, IT

(73) Assignee: IK MULTIMEDIA PRODUCTION S.r.1.

(21) Appl. No.: 09/834,936

(22) Filed: Apr. 16, 2001

(30) Foreign Application Priority Data
Apr. 21, 2000 (IT) M02000A000085

(51) Int. Cl. H03M 7/34

(52) U.S. Cl. 341/51

(57) ABSTRACT

A method for encoding and decoding data streams representing sounds in digital form inside a synthesizer, comprising the steps of:

dividing data streams into a plurality of categories according to the different values assumed by the characteristic parameters that define the data streams, each category being adapted to group the streams that are similar one another in terms of the value assumed by the selected parameter;

using a plurality of encoding algorithms to compress the data streams to be stored in the synthesizer and a plurality of corresponding decoding algorithms to decompress the compressed data streams in order to reproduce the original sounds, each algorithm being particularly suitable to process the data streams that belong to at least one of the categories; and

selecting, for each data stream, the encoding algorithm and the corresponding decoding algorithm that allow the smallest difference between the data stream and, respectively, the compressed and decompressed data streams.

### BACKGROUND OF THE INVENTION

The present invention relates to a method for encoding and decoding data streams representing sounds in digital form inside a synthesizer or other technologies capable of controlling and processing the main parameters of sound in the music field.

As it is known, the computing power of digital processing systems is currently such as to provide, in the field of electronic music, synthesizers capable of offering complex synthesis algorithms and a high level of polyphony.

However, the production of the so-called “rapid access” memories (RAM and ROM) has not undergone the same kind of evolution and is a considerable limitation for synthesizers based on the reproduction of samples, such as samplers.

Samplers in fact synthesize sound by reproducing waveforms stored in RAM, and the overall quality of the synthesis is determined essentially by the possibility to store large quantities of samples and therefore by the size of the memory (RAM).

In order to obviate the shortcomings of current memories, digital instrument manufacturers use part of the computing power of the processor by implementing compression (encoding) and decompression (decoding) algorithms.

In other words, the samples forming the sound are stored by using particular algorithms which are aimed at reducing the amount of memory required.

During the operation of the synthesizer, when the samples are to be reproduced, part of the computing power is used to decode them and convert them into a linear form (so-called PCM or pulse-code modulation).

The algorithms used must be highly efficient in decompression, since they have to produce in real time and simultaneously a number of sample streams equal to the number of polyphony voices of the synthesizer.

At the same time, if the synthesizer has a hardware component dedicated to decompression, the algorithm must be as simple as possible in order to contain the size and cost of said component; if decompression is performed by the same processor that handles synthesis, the algorithm must be as simple as possible, so that its computational burden does not draw from the processor the power required for synthesis.

In most cases, the algorithms used are of the lossy type, i.e. algorithms which during compression remove information from the data stream to be compressed and thereby reduce the size of the stream with respect to its initial size.

Removing information from a sample stream is equivalent to introducing a distortion in the waveform originally represented by the sample stream.

A distortion of the waveform of a sound is perceived by the human ear as a degradation of the quality of the sound with respect to the original sound.

Accordingly, it is common practice to quantify this loss of quality by means of multiple alternated listening tests of the original sound and of the distorted sound, at the end of which a numeric evaluation of the perceived deterioration is given; this evaluation is known as “perceptive quality”.

Conventional algorithms are not devoid of drawbacks, including the fact that they have a limited efficiency, since they process indiscriminately sounds having different characteristic parameters, such as e.g. amplitude or frequency, and that despite entailing a small computational burden they significantly degrade the quality of the sound to be reproduced, especially in the case of high compression ratios, where the expression “compression ratio” designates the ratio between the size of the data item to be compressed and its size after encoding.

### SUMMARY OF THE INVENTION

The aim of the present invention is to eliminate the above-noted drawbacks of conventional algorithms, by providing a method for encoding and decoding data streams representing sounds in digital form inside a synthesizer which has a low computational burden, allows to achieve very high, constant and preset compression ratios, and limits the losses of information and the distortions of the encoded waveform related to each sound, fully to the advantage of a reproduction which is as faithful as possible to the original sound.

An object of the present invention is to improve the decoding of the stored data so as to reproduce, simultaneously and in real time, a plurality of distinct sounds (polyphony and stereophony) while maintaining a high perceptive quality and limiting the complexity and cost of the hardware component, if any, assigned to said decompression or limiting the exploitation of the computing power of the processor of the synthesizer.

A further object of the present invention is to avoid producing distortions in the phase of the waveform of the sound to be compressed.

It is in fact common practice, in synthesizers, to cyclically repeat a portion of stored data (samples), this operation being specifically termed “loop”; if a block of data is looped, when the synthesizer reaches the last data item of the block it resumes reproducing the data starting from the first data item of the block.

This operation is equivalent to appending, one after the other, a plurality of copies of the looped data block, and it is therefore important to have no discontinuities or stepped points in the waveform where joining occurs, thus ensuring continuity between the end and the beginning of the loop.

This aim and these and other objects which will become better apparent hereinafter are achieved by the present method for encoding and decoding data streams representing sounds in digital form inside a synthesizer, comprising the steps of:

dividing said data streams into a plurality of categories according to different values assumed by characteristic parameters that define said data streams, each category being adapted to group the streams that are similar one another in terms of a value assumed by a selected parameter;

using a plurality of encoding algorithms to compress said data streams to be stored in the synthesizer and a plurality of corresponding decoding algorithms to decompress the compressed data streams in order to reproduce the original sounds, each algorithm being particularly adapted to process the data streams belonging to at least one of said categories; and

selecting, for each data stream, the encoding algorithm and the corresponding decoding algorithm that allow a smallest difference between an initial data stream and, respectively, compressed and decompressed data streams.

### DESCRIPTION OF THE PREFERRED EMBODIMENTS

Further characteristics and advantages of the invention will become better apparent from the description of a preferred but not exclusive embodiment of a method for encoding and decoding data streams representing sounds in digital form inside a synthesizer according to the invention.

The method comprises a plurality of encoding algorithms which are adapted to compress the data stream to be stored and a plurality of corresponding decoding algorithms which are adapted to decompress the compressed data in order to be able to reproduce the corresponding original sounds.

According to the different values assumed by some of the characteristic parameters that define sounds, such sounds are divided into a plurality of categories, each of which groups sounds which are similar one another in terms of the value assumed by the selected parameter and differ from each other in terms of the different values assumed by said parameter.

The encoding algorithms and the corresponding decoding algorithms differ from each other in their capacity to specifically process sounds (considered as data streams) belonging to one of these categories, i.e. in their capacity to process the corresponding data streams so as to ensure a constant minimum compression ratio and limit the distortions of the corresponding waveforms, so as to maintain a high perceptive quality of the reproduced sounds.

The system constituted by the set of encoding and decoding algorithms is implemented, for example, in a same synthesizer so as to process a given sound by choosing, among the various available algorithms, the one capable of processing said sound as specifically as possible, i.e. the one that allows to achieve a good compression ratio, for the sake of better exploitation of the memory, and reduced distortion of the corresponding waveform, for the sake of high perceptive quality of the reproduced sound.

The choice of the algorithm to be used for processing (encoding) a sound can be subjective or objective: in the first case, the user is allowed to listen to, and mutually compare, the different versions of the same sound compressed with all the different available algorithms and then to choose the algorithm to be used for that sound according to the best assessed perceptive quality.

In the second case, the method according to the invention comprises an automatic procedure for selecting the algorithm to be used which is based on criteria for analytical evaluation of perceptive quality (waveform degradation).

The automatic selection procedure consists in applying all the available algorithms to the same sound to be compressed, in evaluating the induced degradation of each compressed waveform by analytical calculation of the mean square error with respect to the original waveform, and in choosing the algorithm that produced the smallest error.

Use of evaluation of the mean square error calculated between the compressed waveform (data stream, sound) and the original waveform is such as to lead to results which are very close to those achieved by listening tests.

As an alternative to the above lossy algorithms, it is possible to use lossless algorithms, among which the one characterized by the best compression ratio is selected.

Once the algorithm most suitable for compression (encoding) of the sound in input has been determined, the corresponding decompression (decoding) algorithm is set automatically.

Let N be the number of different encoding algorithms and of the corresponding decompression algorithms, where N is greater than, or equal to, 1; each algorithm is specific in processing sounds belonging to a particular category and having specific characteristics, has a reduced computational burden and ensures limited degradation of the waveform (perceptive quality).

If the two algorithms are lossy, the method according to the present invention comprises a subjective or objective procedure for choosing the algorithm to be used to process a sound to be encoded.

In the case of subjective choice, a same input sound is compressed with the N available algorithms, the user listens to the N compressed sounds so as to assess their corresponding degradations and then selects the algorithm that he deems to be the best, i.e. the one that induces the smallest possible distortion in the waveform that reproduces the original sound.

In the case of objective choice, the corresponding procedure is automatic and consists in compressing the input sound with the N available algorithms, in calculating for each one of the N compressed sounds the value of the parameter taken as selection criterion (mean square error with respect to the original sound), and in choosing as algorithm to be used for compression (encoding) the one characterized by the best value of said parameter (smallest error).

If instead the N algorithms are of the lossless type, the choice is objective and the corresponding procedure consists in determining which algorithm, for that input sound, produces the best compression ratio.

Once the most suitable algorithm for processing the input sound has been determined, the sound is encoded (compressed) in a corresponding data stream which is stored in memory.

At the time of use, i.e. when the sound is reproduced, the stream is decoded (decompressed) by a corresponding decoding algorithm which allows the synthesizer to recreate the sound.

Merely as an example, a system comprising two pairs of data encoding and decoding algorithms (N=2), in which the first pair is specialized in processing sounds having a predominantly low-frequencies spectrum and the second pair is efficient on sounds having a predominantly high-frequency spectrum, can be taken into consideration.

The pair of algorithms that processes sounds having a spectrum in which low frequencies are predominant over high frequencies ensures a constant compression ratio of 2:1.

The encoding algorithm is based on the fact that when the high frequencies have a reduced amplitude, the rate with which the waveform varies is low and the difference between one data item and the next is very small.

This algorithm encodes the difference between the current data item and the preceding one so as to obtain a sequence of numbers whose distribution is a Gaussian distribution whose mean value is nil and whose standard deviation is low, i.e. most of the numbers of the sequence are statistically close to zero.

The encoding algorithm calculates the difference between the value of the current data item and the value of the preceding decompressed data item, uses a nonlinear quantization of the evaluated difference and stores it.

Advantageously, the nonlinear quantization is of the 8-bit type, so that, with a 16-bit input data stream, the compression ratio is 2:1.

Moreover, the nonlinear quantization must have a higher precision for values close to zero and increasingly wider quantization intervals as these values move away from zero.

The corresponding decoding algorithm consists in considering one at a time the codes of the 8 nonlinearly quantized bits, by extracting them in linear form and by adding the resulting value to the preceding decompressed data item.

Extraction of the values from the nonlinear quantized form to the linear form can be performed efficiently by using a table.

Nonlinear quantization of the difference of two values introduces an error; in order to prevent this error from being carried over in all the subsequent data in integration, during compression it is necessary to calculate the difference between the current data item to be compressed and the one obtained after integration of the quantized values.

This type of encoding uses the previously produced data in order to determine the value of the current data item and is therefore particularly adapted when the data are to be reproduced sequentially, as in the case of reproduction of a sampled sound.

If it is necessary to play in a loop (cyclic repetition of a part of data stored in a synthesizer) a data block in order to extend in time the reproduction of a sound, the synthesizer must have available the first data item of the block as soon as the last data item (sample) of the block has been played.

Generally, this data item lies in a generic point of the sequence and it is not possible to resume playback from that point, since the preceding data are not known; one possible solution to this drawback consists in storing, together with the data sequence, the decompressed value of the data item that precedes the beginning of the loop.

As mentioned, the second pair of encoding and decoding algorithms is specialized in processing sounds whose spectrum has a dominance of high frequencies over low ones and also ensures a constant compression ratio of 2:1.

The encoding algorithm is based on the psychoacoustic phenomenon by which distortion is better masked when the spectrum of the input sound has high energy at high frequencies, such as for example the sound of a tenor drum.

This algorithm consists in dividing the data (samples) forming the sound into a plurality of blocks, each of which contains M data items, e.g. M=256, and in determining, for each block, the data item having the highest amplitude in absolute value, designated by the letter A.

The data of the block have values comprised in the interval [−A, A] and the value of A is quantized with 8-bit nonlinear quantization and stored together with the compressed data.

A is then brought to a linear form in order to obtain the corresponding value P.

All the data of the block are normalized according to the maximum amplitude: if R is the bit resolution of the data to be compressed, e.g. R=16, each data item of the block is multiplied by 2^{R}/P.

After normalization, the data of the block are quantized by 8-bit nonlinear quantization and finally compressed.

The corresponding decoding algorithm processes one block at a time; for each block, the value that contains the amplitude of the highest peak (A) is retrieved in memory and is brought from nonlinear quantization to linear quantization (P).

Each data item of the block is returned to the linear form and multiplied by P/2^{R}; the resulting values can be used by the synthesizer to reproduce the original sound.

In practice it has been found that the described invention achieves the intended aim and objects.

The method thus conceived is susceptible of numerous modifications and variations, all of which are within the scope of the appended claims.

All the details may further be replaced with other technically equivalent elements without thereby abandoning the scope of the protection of the appended claims.

The disclosures in Italian Patent Application No. MO2000A000085 from which this application claims priority are incorporated herein by reference.

What is claimed is:

1. A method for encoding and decoding data streams representing sounds in digital form inside a synthesizer, comprising the steps of:
dividing said data streams into a plurality of categories based on different values assumed by characteristic parameters that define said data streams, each category being adapted to group the streams that are similar one another in terms of a value assumed by a selected parameter;
using a plurality of encoding algorithms to compress said data streams to be stored in the synthesizer and a plurality of corresponding decoding algorithms to decompress the compressed data streams in order to reproduce the original sounds, each algorithm being particularly suitable to process the data streams belonging to at least one of said categories; and
selecting, for each data stream, the encoding algorithm and the corresponding decoding algorithm that allow a smallest difference between said data stream and, respectively, the compressed and decompressed data streams.

2. The method according to claim 1, wherein said algorithms are suitable to ensure a constant minimum compression ratio and to limit the distortions of waveforms related to the data streams.

3. The method according to claim 1, wherein the data streams within each category are distinguished one from the other according to the different values assumed by the corresponding parameter.

4. The method according to claim 2, wherein said step of selecting the algorithm is objective and consists of an automatic algorithm selection procedure being substantially based on criteria of analytical evaluation of degradation of the waveform.

5. The method according to claim 4, wherein said automatic algorithm selection procedure consists in compressing a same data stream with said encoding algorithms, evaluating the degradation of the waveform of each compressed version of the stream by calculating analytically the mean square error with respect to the waveform of the original stream, and choosing the algorithm that produces the smallest square error.

6. The method according to claim 1, wherein pairs formed by said encoding algorithms and by the corresponding decoding algorithms are at least two in number, a first pair being adapted to process data streams representing sounds whose spectra have a dominance at low frequencies and a second pair being adapted to process data streams representing sounds whose spectra have a dominance at high frequencies.

7. The method according to claim 6, wherein the encoding algorithm of said first pair consists in calculating the difference between the value of the current data item and the value of the preceding compressed data item, nonlinearly quantizing the calculated difference, and storing it.

8. The method according to claim 7, wherein said nonlinear quantization is more precise for values close to zero and has increasingly wider intervals as said values move away from zero.

9. The method according to claim 7, wherein the decoding algorithm of said first pair consists in bringing the encoded data to a linear form by reversing a nonlinear quantization and adding a resulting value to a value of the preceding decompressed data item.

10. The method according to claim 7, wherein the encoding algorithm of said second pair consists in dividing the data of the stream into a plurality of blocks; determining, for each block, the data item having the highest amplitude in absolute value; normalizing all the data of the block on the basis of said maximum amplitude; nonlinearly quantizing the normalized data; and storing the normalized data together with a multiplication constant used for normalization.

11. The method according to claim 10, wherein the decoding algorithm of said second pair consists in returning to a linear form the data of each block by reversing the quantization and multiplying said data by an inverse of said multiplication constant in order to reproduce the original sound.

12. The method according to claim 2, wherein said step of selecting the algorithm is subjective and consists in listening to, and mutually comparing, different versions of a same data stream compressed with said encoding algorithms and choosing the algorithm that determines the smallest degradation of the waveform.

13. The method according to claim 1, consisting in selecting the algorithms that allow the best compression ratio.

14. The method according to claim 13, wherein said compression ratio is constant and equal to 2:1.
